(19) United States
(12) Patent Application Publication
(10) Pub. No.: US 2014/0216790 A1
(43) Pub. Date: Aug. 7, 2014

(54) CONDUCTIVE MICRO-WIRE STRUCTURE WITH OFFSET INTERSECTIONS

(71) Applicants: David P. Trauernicht, Rochester, NY (US); John A. Lebens, Rush, NY (US); Yongcai Wang, Rochester, NY (US)

(72) Inventors: David P. Trauernicht, Rochester, NY (US); John A. Lebens, Rush, NY (US); Yongcai Wang, Rochester, NY (US)

(21) Appl. No.: 13/759,106

(22) Filed: Feb. 5, 2013

(51) Int. Cl. H05K 1/02

(52) U.S. Cl. CPC H05K 1/0274
USPC 174/253

(57) ABSTRACT

A conductive micro-wire structure includes a substrate and a plurality of micro-wires formed on or in the substrate in an intersecting pattern and forming intersection corners. A portion of a first micro-wire is coincident with a portion of a second micro-wire to form a coincident portion such that the coincident portion is non-visually resolvable by the human visual system and the coincident portion has a length greater than the sum of the widths of the first and second micro-wires or has one or more rounded intersection corners.

### CROSS REFERENCE TO RELATED APPLICATIONS

Reference is made to commonly-assigned U.S. patent application Ser. No. ______ (Docket K001292) filed concurrently herewith, entitled MICRO-WIRE PATTERN WITH OFFSET INTERSECTIONS, and commonly-assigned U.S. patent application Ser. No. 13/571,704 filed Aug. 10, 2012, entitled MICRO-WIRE ELECTRODE PATTERN, the disclosures of which are incorporated herein.

### FIELD OF THE INVENTION

The present invention relates to patterns and conductive structures for micro-wire electrical conductors.

### BACKGROUND OF THE INVENTION

Transparent conductors are widely used in the flat-panel display industry to form electrodes for electrically switching the light-emitting or light-transmitting properties of a display pixel, for example in liquid crystal or organic light-emitting diode displays. Transparent conductive electrodes are also used in touch screens in conjunction with displays. In such applications, the transparency and conductivity of the transparent electrodes are important attributes. In general, it is desired that transparent conductors have a high transparency (for example, greater than 90% in the visible spectrum) and a low electrical resistivity (for example, less than 10 ohms/square).

Touch screens with transparent electrodes are widely used with electronic displays, especially for mobile electronic devices. Such devices typically include a touch screen mounted over an electronic display that displays interactive information. Touch screens mounted over a display device are largely transparent so a user can view displayed information through the touch-screen and readily locate a point on the touch-screen to touch and thereby indicate the information relevant to the touch. By physically touching, or nearly touching, the touch screen in a location associated with particular information, a user can indicate an interest, selection, or desired manipulation of the associated particular information. The touch screen detects the touch and then electronically interacts with a processor to indicate the touch and touch location. The processor can then associate the touch and touch location with displayed information to execute a programmed task associated with the information. For example, graphic elements in a computer-driven graphic user interface are selected or manipulated with a touch screen mounted on a display that displays the graphic user interface.

Referring to FIG. 10, a prior-art display and touch-screen system 100 includes a display 110 having a display area 111. A corresponding touch screen 120 is mounted with display 110 so that information displayed on display 110 in display area 111 can be viewed through touch screen 120. Graphic elements displayed on the display 110 in display area 111 are selected, indicated, or manipulated by touching a corresponding location on touch screen 120. Touch screen 120 includes a first transparent substrate 122 with first transparent electrodes 130 formed in the x dimension on first transparent substrate 122 and a second transparent substrate 126 with second transparent electrodes 132 formed in the y dimension facing the x-dimension first transparent electrodes 130 on second transparent substrate 126. A dielectric layer 124 is located between first and second transparent substrates 122, 126 and first and second transparent electrodes 130, 132. Referring also to the plan view of FIG. 11, in this example first pad areas 128 in first transparent electrodes 130 are located adjacent to second pad areas 129 in second transparent electrodes 132 in display area 111. (First and second pad areas 128, 129 are separated into different parallel planes by dielectric layer 124.) First and second transparent electrodes 130, 132 have a variable width and extend in orthogonal directions (for example as shown in U.S. Patent Application Publication Nos. 2011/0289771 and 2011/0099805). When a voltage is applied across first and second transparent electrodes 130, 132, electric fields are formed between first pad areas 128 of x-dimension first transparent electrodes 130 and second pad areas 129 of y-dimension second transparent electrodes 132.

A display controller 142 (FIG. 10) connected through electrical buss connections 136 controls display 110 in cooperation with a touch-screen controller 140. Touch-screen controller 140 is connected through electrical buss connections 136 and wires 134 outside display area 111 and controls touch screen 120. Touch-screen controller 140 detects touches on touch screen 120 by sequentially electrically energizing and testing x-dimension first and y-dimension second transparent electrodes 130, 132.

Referring to FIG. 12, in another prior-art embodiment, rectangular first and second transparent electrodes 130, 132 are arranged orthogonally in display area 111 projected from display 110 onto first and second transparent substrates 122, 126 with intervening dielectric layer 124, forming touch screen 120 which, in combination with display 110 forms touch screen and display system 100. First and second pad areas 128, 129 are formed where first and second transparent electrodes 130, 132 overlap. Touch screen 120 and display 110 are controlled by touch screen and display controllers 140, 142, respectively, through electrical busses 136 and wires 134 outside display area 111.

The electrical busses 136 and wires 134 are electrically connected to first or second transparent electrodes 130, 132 but are located outside display area 111. However, at least a portion of electrical busses 136 or wires 134 are formed on touch screen 120 to provide the electrical connection to first or second transparent electrode 130, 132. It is desirable to maximize the size of display area 111 with respect to the entire display 110 and touch screen 120. Thus, it can be helpful to reduce the size of wires 134 and busses 136 in touch screen 120 outside display area 111. At the same time, to provide excellent electrical performance, wires 134 and busses 136 need a low resistance. Furthermore, to reduce manufacturing costs, it is desirable to reduce the number of manufacturing steps and materials in touch screen 120.

Touch-screens including very fine patterns of conductive elements, such as metal wires or conductive traces are known. For example, U.S. Patent Application Publication No. 2010/0026664 teaches a capacitive touch screen with a mesh electrode, as does U.S. Pat. No. 8,179,381. Referring to FIG. 13, a prior-art x- or y-dimension first or second variable-width transparent electrode 130, 132 includes a micro-pattern 156 of micro-wires 150 arranged in a rectangular grid. The micro-wires 150 are multiple very thin metal conductive traces or wires formed on the first and second transparent substrates 122, 126 (not shown in FIG. 13) to form the x- or y-dimension first or second transparent electrodes 130, 132. The micro-wires 150 are so narrow that they are not readily visible to a human observer, for example 1 to 10 microns wide. The micro-wires 150 are typically opaque and spaced apart, for example by 50 to 500 microns, so that the first or second transparent electrodes 130, 132 appear to be transparent and the micro-wires 150 are not distinguished by an observer.

U.S. Patent Application Publication No. 2011/0291966 discloses an array of diamond-shaped micro-wire structures. Known micro-patterns of micro-wires in a transparent electrode include diamond-shapes, rectangular meshes, random, sine-wave meshes, circles, and a brick pattern. Referring to FIG. 14, this prior-art design includes micro-wires 150 arranged in a micro-pattern 156 with the micro-wires 150 oriented at an angle to the direction of horizontal first transparent electrodes 130 in a first layer (e.g. first transparent substrate 122 in FIG. 12) and vertical second transparent electrodes 132 in a second layer (e.g. second transparent substrate 126 in FIG. 12).

A variety of layout patterns are known for micro-wires used in transparent electrodes. U.S. Patent Application Publication No. 2012/0031746 discloses a number of micro-wire electrode patterns, including regular and irregular arrangements. The conductive pattern of micro-wires in a touch screen can be formed by closed figures distributed continuously in an area of 30% or more, preferably 70% or more, and more preferably 90% or more of an overall area of the substrate and can have a shape where a ratio of standard deviation for an average value of areas of the closed figures (a ratio of area distribution) can be 2% or more. As illustrated in FIG. 15, U.S. Patent Application Publication No. 2011/0007011 teaches a first or second transparent micro-wire electrode 130, 132 having micro-wires 150 arranged in a micro-wire pattern 156.

However, as noted above, it is useful to reduce visibility of micro-wire structures in a transparent electrode and improve electrical connectivity. It is also useful to improve conductivity when producing electrically conductive structures. There is a need, therefore, for an improved micro-wire pattern, and an electrically conductive structure based on the improved micro-wire pattern, that is compatible with transparent electrodes, provides improved conductivity and connectivity, reduces visibility of the micro-wire patterns, and is robust in the presence of faults.

### SUMMARY OF THE INVENTION

In accordance with the present invention, a conductive micro-wire structure is provided. The conductive micro-wire structure comprises a substrate and a plurality of micro-wires arranged in an intersecting pattern forming intersection corners, wherein a portion of a first micro-wire is coincident with a portion of a second micro-wire to form a coincident portion such that the coincident portion is non-visually resolvable the human visual system and the coincident portion has a length greater than the sum of the widths of the first and second micro-wires or has rounded intersection corners.

The present invention provides a conductive micro-wire structure with offset intersections so that intersection points have three intersecting elements. This improves conductivity and reduces visibility of the intersections, since micro-wires cracks are reduced and the intersections are smaller. The present invention is robust in the presence of faults in the micro-wires. A conductive micro-wire structure using the present invention can form a transparent micro-wire electrode.

### BRIEF DESCRIPTION OF THE DRAWINGS

The above and other features and advantages of the present invention will become more apparent when taken in conjunction with the following description and drawings wherein identical reference numerals have been used to designate identical features that are common to the figures, and wherein:

FIGS. 1-4 are plan views of various conductive micro-wires arranged in patterns according to embodiments of the present invention;

FIG. 5 is an illustration of a conductive micro-wire structure pattern according to another embodiment of the present invention;

FIGS. 6 and 7 are schematics illustrating patterns according to embodiments of the present invention;

FIG. 8 is a plan view of a conductive micro-wire structure pattern in or on a substrate;

FIG. 9A is a cross section of an embossed micro-channel useful with the present invention;

FIG. 9B is cross section of a micro-wire useful with the present invention;

FIG. 9C is another cross section of another embossed micro-channel useful with the present invention;

FIG. 10 is an exploded perspective illustrating a prior-art mutual capacitive touch screen having adjacent pad areas in conjunction with a display and controllers;

FIG. 11 is a schematic illustrating prior-art pad areas in a capacitive touch screen;

FIG. 12 is an exploded perspective illustrating a prior-art mutual capacitive touch screen having overlapping pad areas in conjunction with a display and controllers;

FIG. 13 is a schematic illustrating prior-art micro-wires in an apparently transparent electrode.

FIG. 14 is a schematic illustrating prior-art transparent micro-wire electrodes arranged in two arrays of orthogonal transparent electrodes;

FIG. 15 is a schematic illustrating a prior-art transparent micro-wire electrode; and

FIGS. 16-19 are flow diagrams illustrating methods useful in the present invention.

The Figures are not necessarily to scale, since the range of dimensions in the drawings is too great to permit depiction to scale.

### DETAILED DESCRIPTION OF THE INVENTION

The present invention is directed toward electrically conductive micro-wire structures formed on or in a substrate. The electrically conductive micro-wire structures are robust in the presence of faults in the micro-wires and can form transparent micro-wire electrodes. As used herein, the substrates are not integrated circuit substrates and are of a size with which a human user can directly interact. The electrically conductive micro-wire structures of the present invention can also be useful in other applications and are not limited to applications having transparent micro-wire electrodes.

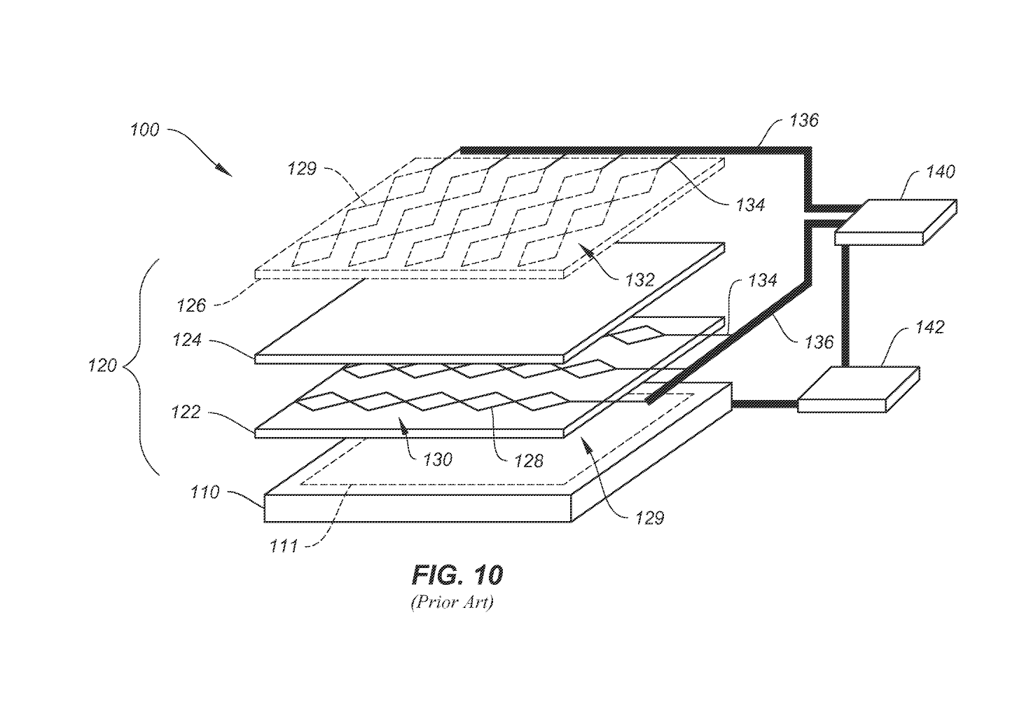

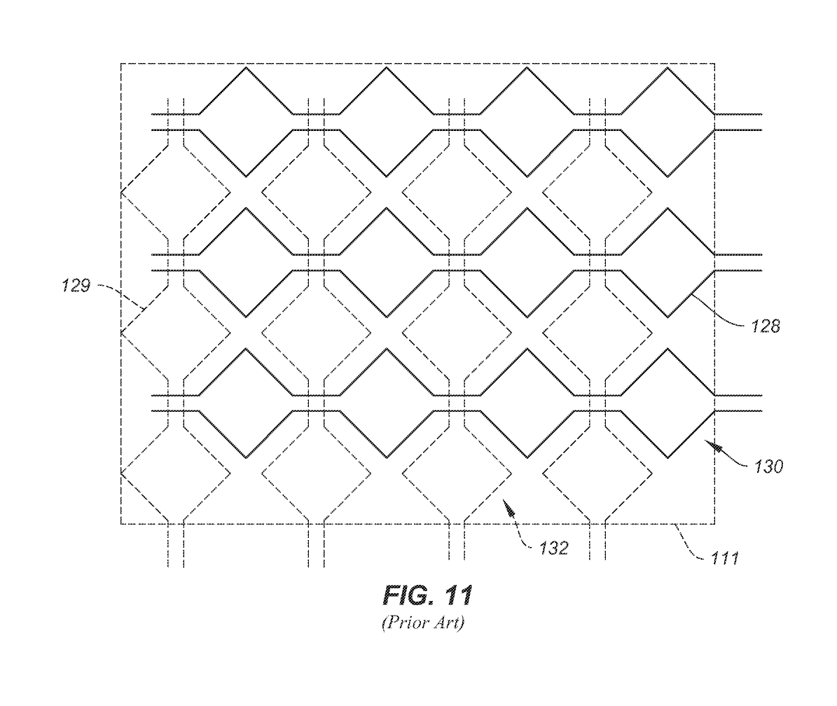

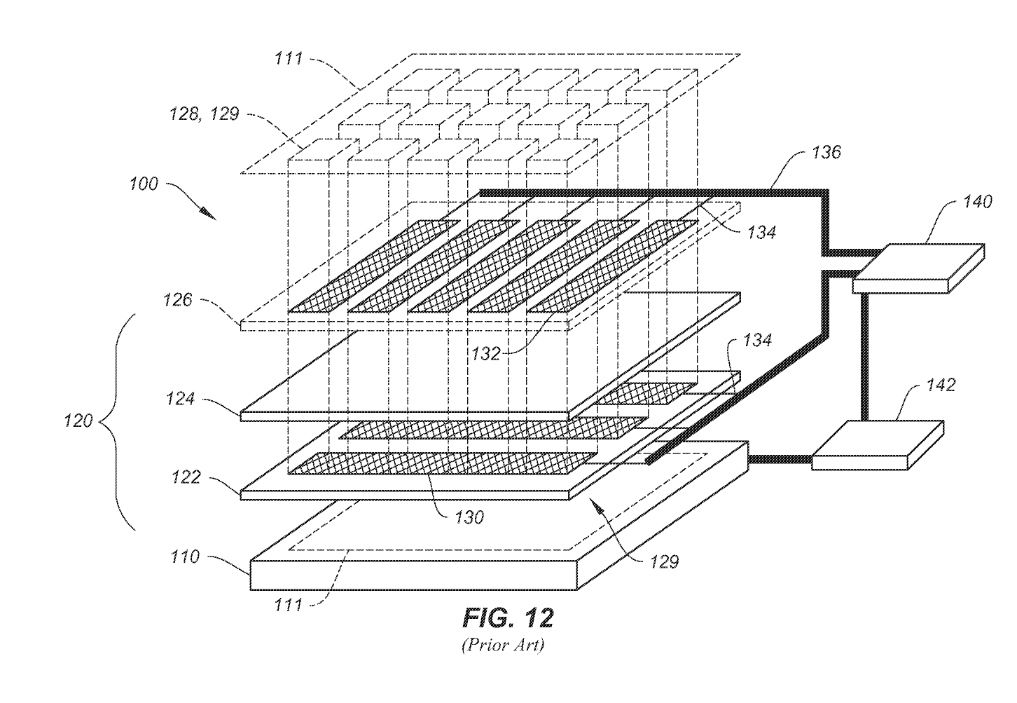

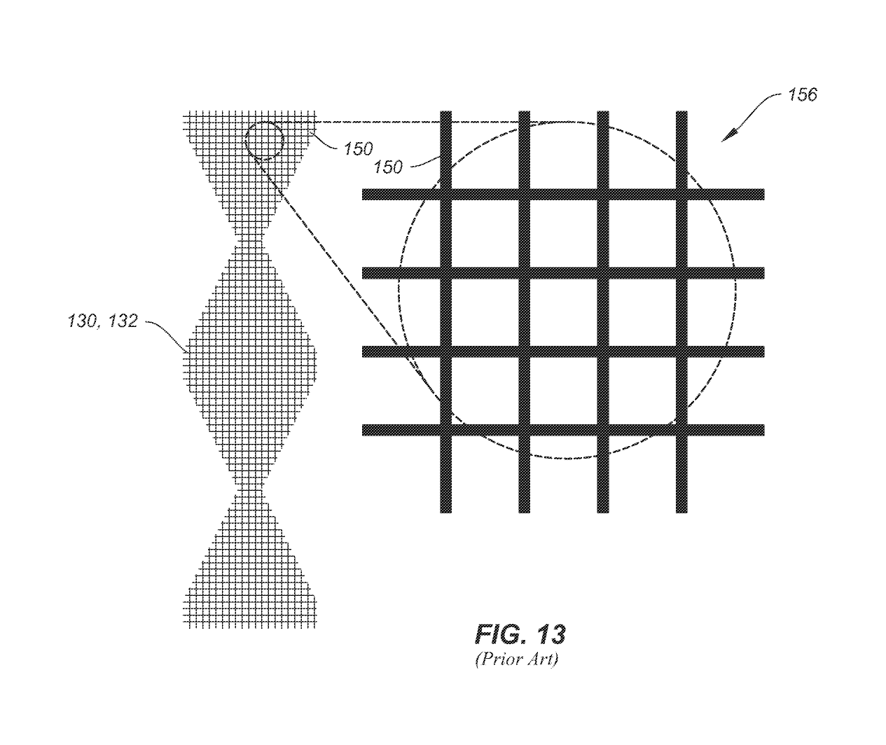

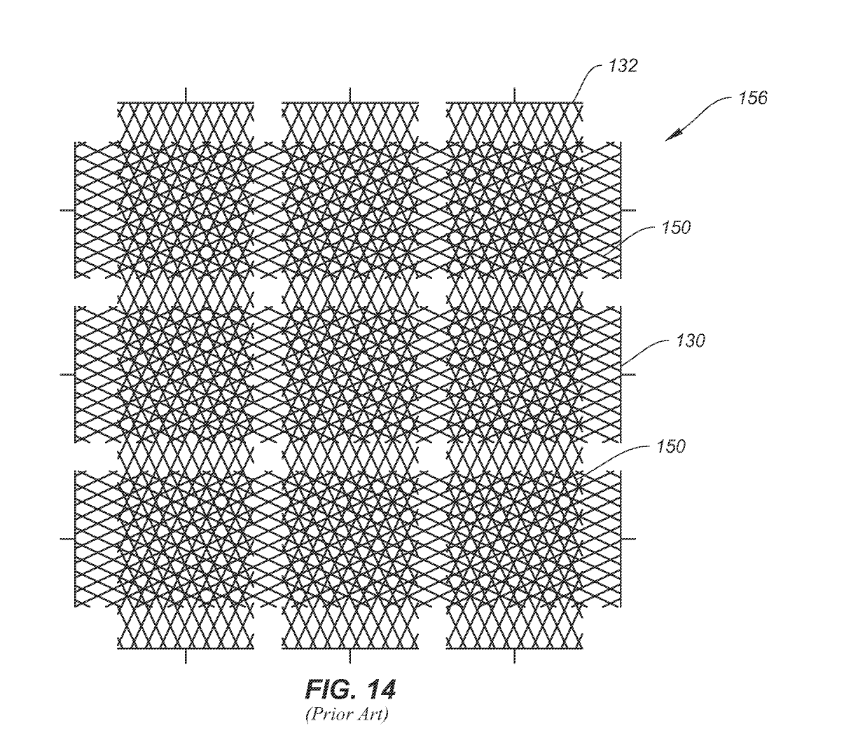

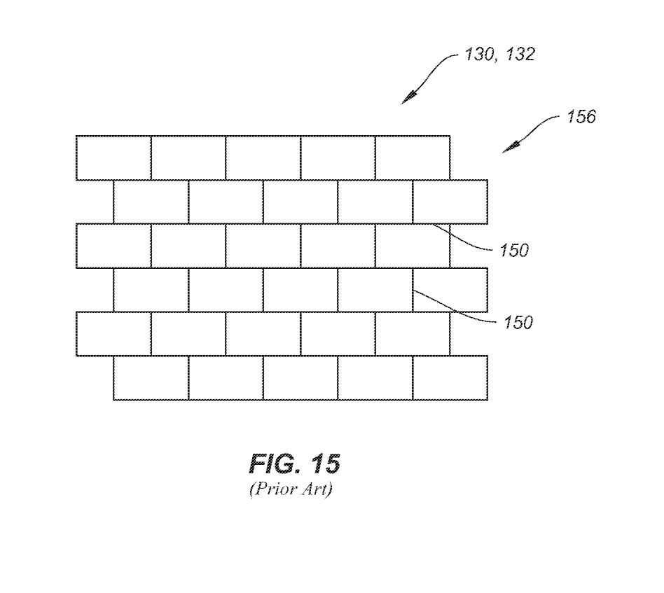

In particular, transparent micro-wire electrodes known in the prior art including spaced-apart micro-wires located on either side of a dielectric layer are known for making capacitive touch screens (e.g. as illustrated in FIGS. 10-15 and discussed above). An objective of such prior-art transparent micro-wire electrodes is to provide both transparency and conductivity over the extent of a substrate, for example over the display area of a capacitive touch screen (e.g. display area 111 and touch screen 120 of FIG. 12).

According to embodiments of the present invention, electrically conductive micro-wires structures provide greater conductivity and reduced visibility. The present invention reduces manufacturing costs and does not further reduce the range of materials that can be used in a substrate having micro-wire electrical conductors formed thereon.

The electrically conductive micro-wire structures of the present invention can be used to make electrical conductors and busses for electrically connecting transparent micro-wire electrodes to electrical connectors or controllers such as integrated circuit controllers. One or more electrically conductive micro-wire structures can be used in a single substrate and can be used, for example in touch screens that use transparent micro-wire electrodes. The electrically conductive micro-wire structures can be located in areas other than display areas, for example in the perimeter of the display area of a touch screen, where the display area is the area through which a user views a display.

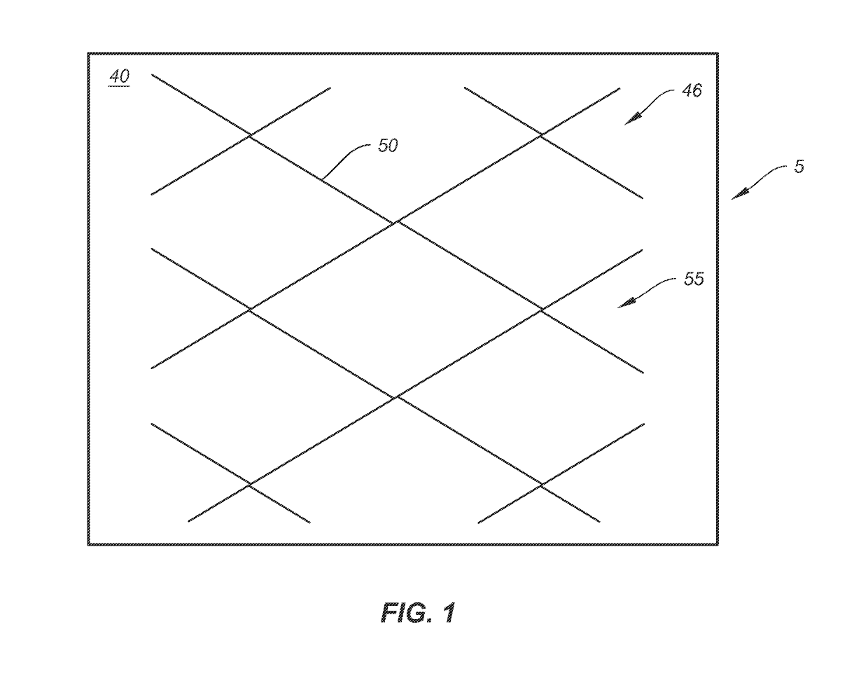

Referring to FIG. 1, in an embodiment of the present invention, a transparent micro-wire electrode 46 forming a conductive micro-wire structure 5 is formed in or on a substrate 40. A plurality of electrically connected micro-wires 50 is formed in or on substrate 40 in an intersecting pattern 55 of micro-wires 50.

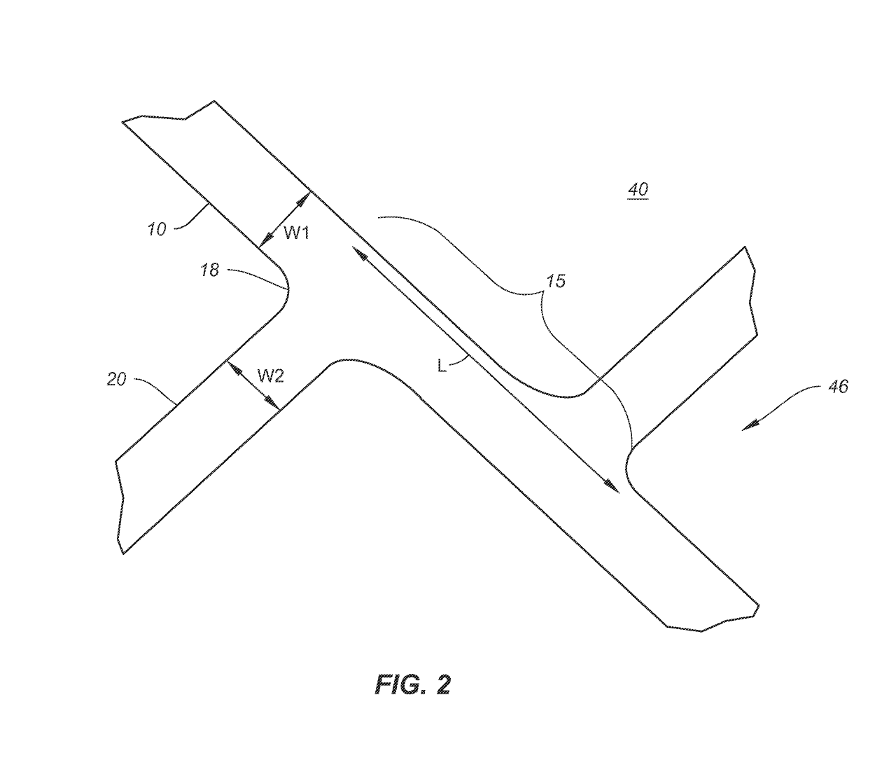

Referring to the micro-graphic image FIG. 2 in more detail, a first micro-wire 10 and a second micro-wire 20 formed in or on substrate 40 intersect and a portion 15 of first micro-wire 10 is coincident with a portion of micro-wire 20. Because first micro-wire 10 and second micro-wire 20 intersect and have a coincident portion 15, the intersections have a ‘T’ shape with two intersection corners 18 each. In one embodiment of the present invention, the coincident portion 15 is non-visually resolvable by the human visual system (i.e. cannot be resolved by the naked human eye) and the coincident portion has a length L greater than the sum of the widths W1, W2 of first and second micro-wires 10, 20, respectively. The length L includes the widths W1, W2 of first and second micro-wires 10, 20.

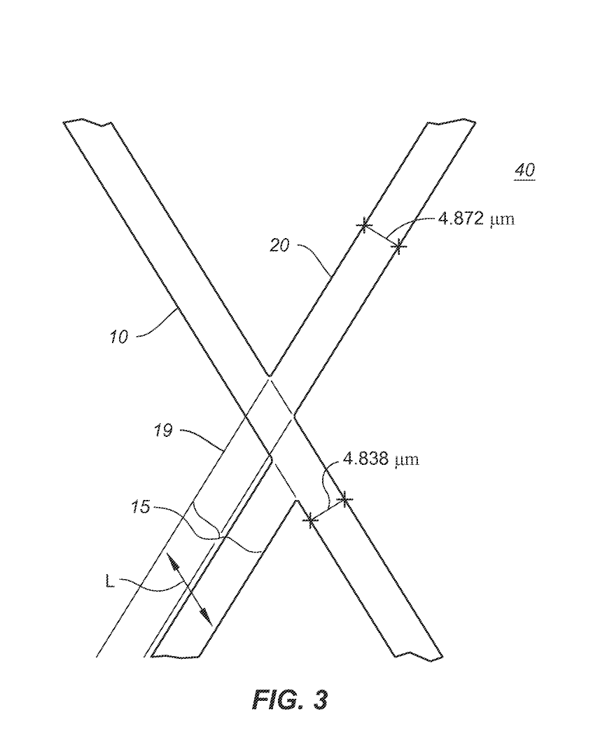

FIG. 3 is a micro-graphic image of first and second micro-wires 10, 20 formed by embossing micro-wires into substrate 40. Extension lines 19 illustrate the path of micro-wire 20 absent coincident portion 15 and demonstrate that coincident portion 15 has length L greater than twice the width of micro-wire 20. Because length L includes the widths of first and second micro-wires 10, 20, extension lines 19 of second micro-wire 20 on one side of coincident portion 15 does not overlap with second micro-wire 20 on the other side of coincident portion 15.

By providing rounded corners and offset intersection, the present invention provides improved conductivity and reduced visibility for micro-wire intersecting patterns 55. Because the intersections are offset, the amount of material at a single point is reduced, reducing the visibility of the material at the intersection. It has been difficult to avoid some deposition of additional material at intersections (increasing the visibility of the intersections). Thus, by offsetting the intersections, the amount of additional material that is deposited at a given point is reduced, improving apparent transparency. This is an important feature of this invention. Furthermore, by providing rounded corners, cracking of deposited conductive materials (e.g. metal) is reduced, particularly if the conductive materials are deposited as a liquid and then dried to form micro-wires 50. Offset intersections also improve material deposition and reduce cracking. By reducing cracking, conductivity of micro-wires 50 is improved. In particular, it has been demonstrated that micro-wires formed in embossed micro-channels, as discussed further below, have reduced cracking, improved conductivity, and reduced visibility when offset intersections are used, as disclosed herein.

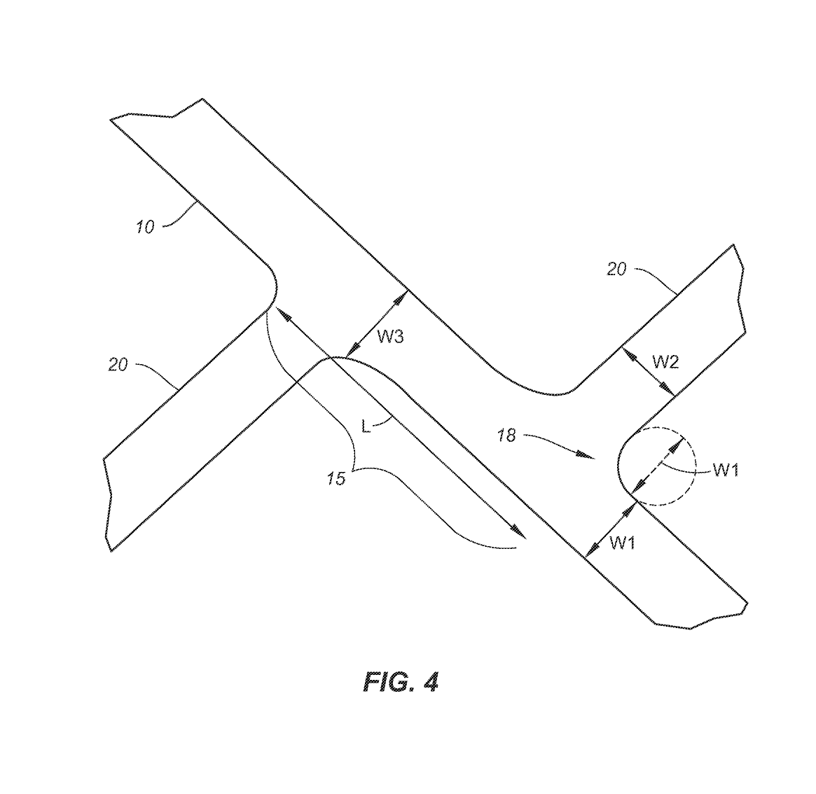

Referring to FIG. 4, in another embodiment, the coincident portion 15 has at least one rounded intersection corner 18. Intersection corner 18 is a corner formed by the intersection of first and second micro-wire 10, 20, and can be any one of the four corners formed by the intersection. It has been found advantageous to have intersection corners 18 having a radius of curvature greater than or equal to one half of micro-wire width W1 or W2. In the example of FIG. 4, W1 and W2 are equal and a circle C illustrating the radius of curvature of intersection corner 18 is shown. Width W1 is shown as a partial diameter, illustrating that the radius of curvature of intersection corner 18 is greater than one half of width W 1, since W1 is less than the diameter of the circle and the radius of the circle is one half of the diameter. In another embodiment, the radius of curvature of the one or more intersection corners has a radius of curvature greater than or equal to one third of the micro-wire width. In another embodiment, the radius of curvature of the one or more intersection corners has a radius of curvature greater than or equal to one quarter of the micro-wire width.

In an embodiment, coincident portion 15 has a length less than a predetermined viewing distance multiplied by the tangent of a predetermined human resolution angle such that the intersections of the micro-wires are not visually resolvable and the human visual system is incapable of resolving the intersections without artificial aid (e.g. a microscope). The value calculated defines the resolvable separation for a human observing two parallel separated lines.

Thus, in FIG. 4, a pattern of electrically connected micro-wires 50 includes first micro-wires 10 and second micro-wires 20 intersecting with first micro-wire 10 forming intersection corners 18. At least one intersection corner 18 joining first micro-wire 10 with second micro-wire 20 is rounded and has a radius of curvature greater than one half of the width of first or second micro-wire 10, 20. In particular, it has been demonstrated that micro-wires formed in embossed micro-channels, as discussed further below, have reduced visibility when rounded corners are used, as disclosed herein.

Also shown in FIG. 4, the coincident portion 15 of the first and second micro-wires 10, 20 has a width W3 greater than the largest width W1, W2 of the first or second micro-wires 10, 20. As shown, the width W3 can be the average width of coincident portion 15 or the width of coincident portion 15 at any point along length L of coincident portion 15.

As shown in FIG. 1, first or second micro-wires 10, 20 have straight line segments. The first micro-wires 10 can form a first array of parallel equally spaced micro-wire segments and second micro-wires 20 can form a second array of parallel equally spaced micro-wire segments. First and second micro-wires 10, 20 can intersect at one of about 60 degrees, 90 degrees, or 120 degree angles, to form rhomboids of various aspect ratios and having a variety of interior angles, such as rectangles, square, or diamonds. The micro-wires can also form hexagons with first and second micro-wires 10, 20.

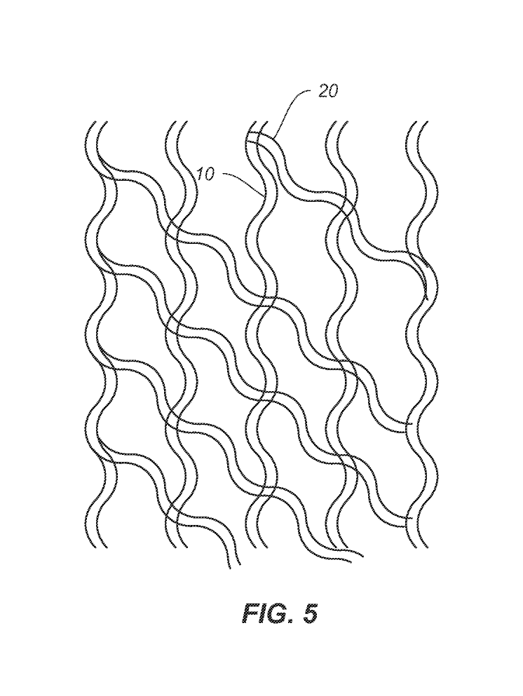

Alternatively, first or second micro-wires 10, 20 are curved, for example forming a pattern of repeating curves as illustrated in FIG. 5. The intersecting pattern 55 can have micro-wires with curved or circular segments and the coincident portion 15 is straight.

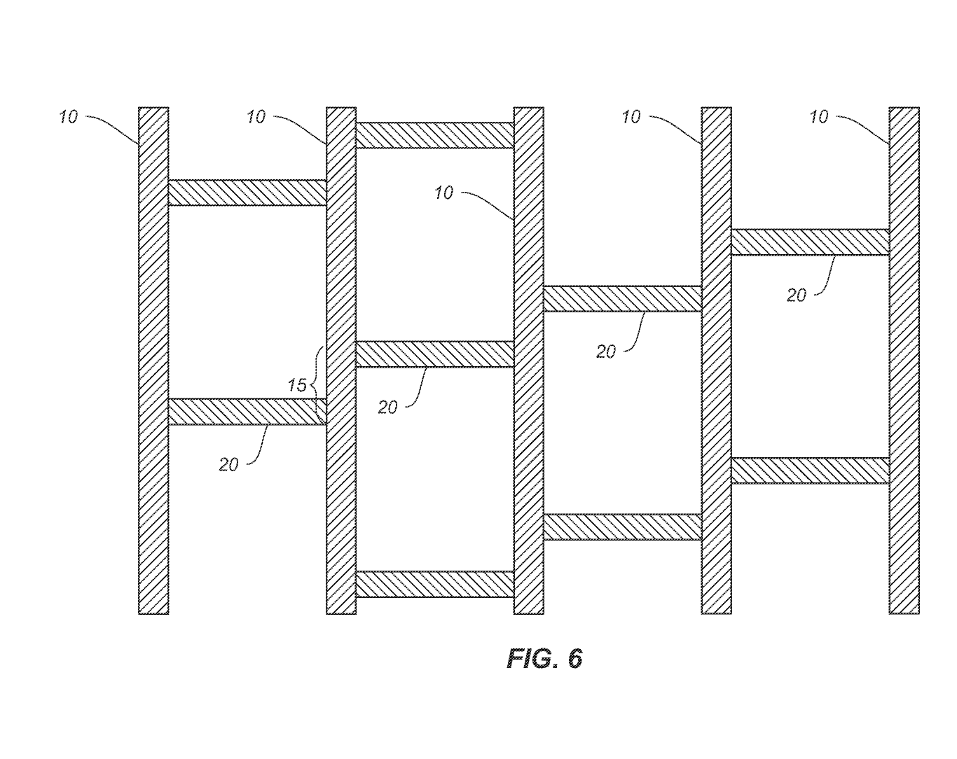

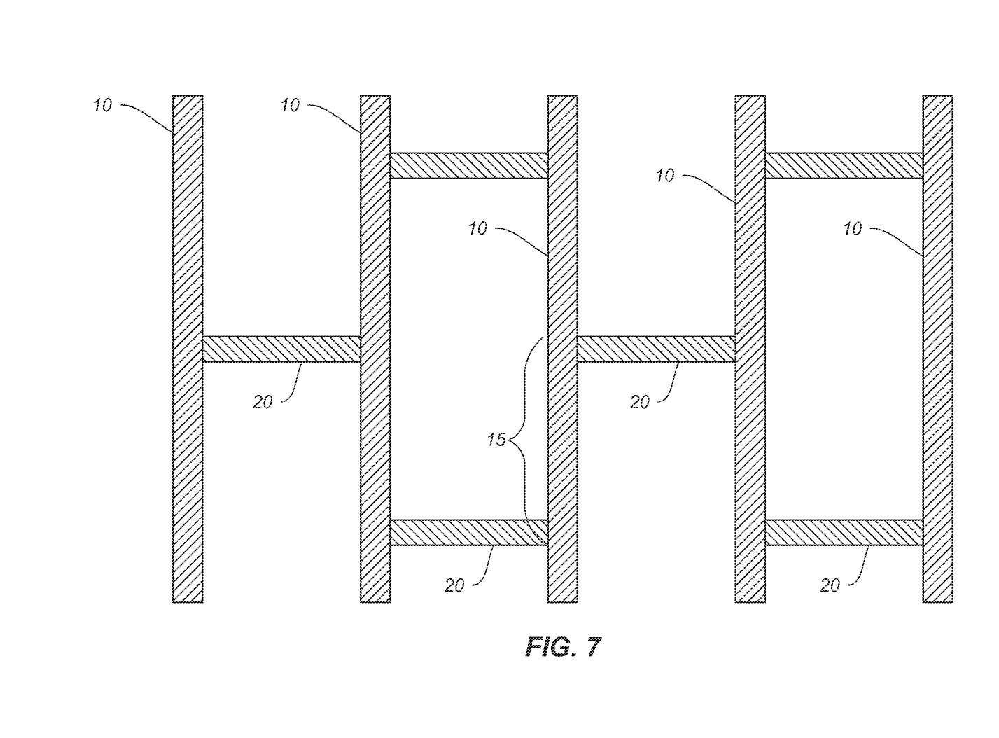

Referring to FIG. 6, in an embodiment, first and second micro-wires 10, 20 and intersections with coincident portions 15 form a step-type pattern. As shown in FIG. 7, in another embodiment, first and second micro-wires 10, 20 and intersections with coincident portions 15 form a square wave pattern.

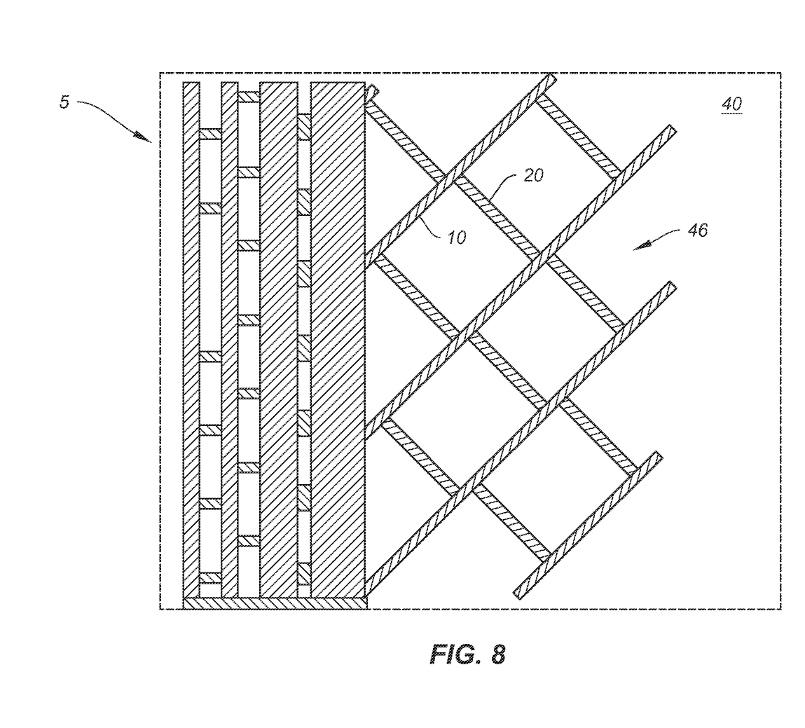

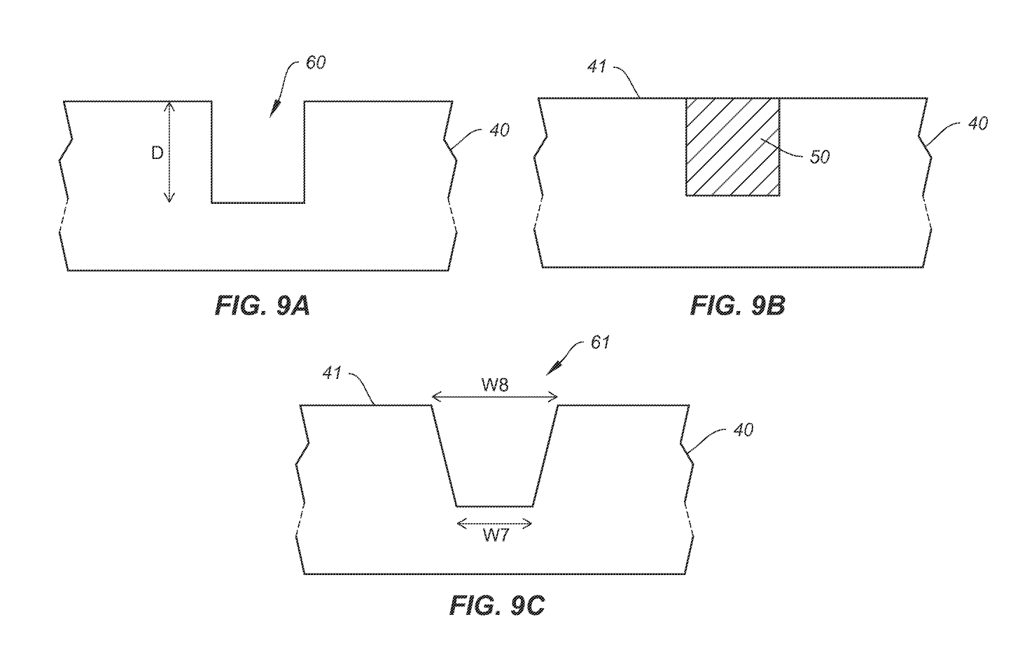

Referring to FIG. 8, micro-wires 50 can be formed on a substrate 40, for example by embossing or printing metal micro-wires in an intersecting pattern 55 to form a substantially transparent electrode 46. Thus, in an embodiment of the present invention, a conductive micro-wire structure includes a substrate 40, a plurality of micro-wires 50 formed on or in the substrate 40 and arranged in an intersecting pattern 55 forming intersection corners 18. A portion of first micro-wire 10 is coincident with a portion of second micro-wire 20 to form a coincident portion 15 such that coincident portion 15 is non-visually resolvable by the human visual system and the coincident portion 15 has a length L greater than the sum of the widths W1, W2 of first and second micro-wires 10, 20. Alternatively, coincident portion 15 has one or more rounded intersection corners. Each micro-channel 60 (shown in FIG. 9A) can include a micro-wire 50 (shown in FIG. 9B).

Substrate 40 on or in which conductive micro-wire structure 5 is formed can define a plurality of micro-channels 60 each of which contains a micro-wire 50A cross section of at least one of the micro-channels is rectangular (as shown in FIG. 9A) or trapezoidal (FIG. 9C). Preferably, a depth D of rectangular micro-channel 60 is at least 2 microns and at most 10 microns. In a further embodiment, the conductive micro-wire structure 5 forms a substantially transparent electrode 46. Transparent electrode 46 can be electrically connected to an electronic device having integrated circuits that control substantially transparent electrode 46.

A conductive micro-wire structure 5 includes substrate 40, first micro-wire 10 formed on or in substrate 40 and second micro-wire 20 formed on or in substrate 40 and intersecting with first micro-wire 10 forming intersection corners 18. At least one intersection corner 18 joining first micro-wire 10 with second micro-wire 20 is rounded and has a radius of curvature greater than one half of the width W1, W2 of the first or second micro-wire 10, 20 respectively. Alternatively, width W1 of first micro-wire 10 is equal to width W2 of second micro-wire 20.

Substrate 40 can be a cured polymer and micro-wires 50 are embossed in substrate 40. Substrate 40 can be formed on an underlying substrate, for example made of glass or plastic.

Substrate 40 can be a rigid or a flexible substrate 40 made of, for example, a glass or polymer material, can be transparent, or can have opposing substantially parallel and extensive surfaces. Substrates 40 can include a dielectric material useful for capacitive touch screens and can have a wide variety of thicknesses, for example 10 microns, 50 microns, 100 microns, 1 mm, or more. Substrates 40 can be provided as a separate structure or are coated on another underlying substrate, for example by coating a polymer substrate layer on an underlying glass substrate. Such substrates 40 and their methods of construction are known in the prior art. Substrate 40 can be an element of other devices, for example the cover or substrate of a display or a substrate or dielectric layer of a touch screen.

Substrate 40 of the present invention can include any material capable of providing a supporting surface on which micro-wires 50 can be formed and patterned. Substrates such as glass, metal, or plastic can be used and are known in the art together with methods for providing suitable surfaces. Substrate 40 can be substantially transparent, for example having a transparency of greater than 90%, 80% 70% or 50% in the visible range of electromagnetic radiation.

Micro-wires 50 (e.g. first and second micro-wires 10, 20) can extend across substrate 40. By “extend across” is meant that micro-wires 50 are longer than they are wide and the length of micro-wires 50 is in a direction parallel to a surface of substrate 40. The length of first or second micro-wires 10, 20 is typically less than the size of a surface of substrate 40 in any planar dimension. In particular, “extend across” does not mean that any micro-wire 50 has a length equal to the size of any planar surface dimension of substrate 40 or extends all of the way across substrate 40 from one edge of substrate 40 to another.

The present invention includes a wide variety of micro-wire intersecting patterns 55 and variations in micro-wires 50, for example having different or varying widths. Micro-wires 50 can have a reduced width but an increased thickness, for example having a thickness greater than a width, to provide increased conductivity and reduced width, thereby enhancing conductivity and transparency. Such micro-wires, when made by a suitable method, can have a conductivity of less than or equal to 4 ohms per square, less than or equal to 3 ohms per square, less than or equal to 2 ohms per square, or less than or equal to 1 ohm per square.

Alternatively, one or more of first or second micro-wires 10, 20 has a width of greater than or equal to 0.5 μm and less than or equal to 20 μm to provide an apparently transparent micro-wire electrode 46.

A variety of methods can be used to make micro-wires 50 of electrically conductive micro-wire structure 5. Some of these methods are, for example, taught in CN102063951 and commonly assigned U.S. application Ser. No. 13/571,704, which is hereby incorporated by reference in its entirety. As discussed in CN102063951, a pattern of micro-channels 60 can be formed in a substrate using an embossing technique. Embossing methods are generally known in the prior art and typically include coating a curable liquid, such as a polymer, onto a rigid substrate. The polymer is partially cured (e.g. through heat or exposure to light or ultraviolet radiation) and then a pattern of micro-channels is embossed (impressed) onto the partially cured polymer layer by a master having a reverse pattern of ridges formed on its surface. The polymer is completely cured. A conductive ink is then coated over substrate 40 and into micro-channels 60, the excess conductive ink between micro-channels 60 is removed, for example by mechanical buffing, patterned chemical electrolysis, or patterned chemical corrosion. The conductive ink in the micro-channels is cured, for example by heating.

In an alternative method described in CN102063951, a photosensitive layer, chemical plating, or sputtering is used to pattern conductors, for example using patterned radiation exposure or physical masks. Unwanted material (e.g. photosensitive resist) is removed, followed by electro-deposition of metallic ions in a bath.

Other methods can be employed. Inkjet deposition of conductive inks is known in the art, as is printing conductive inks, for example using gravure offset printing, flexographic printing, pattern-wise exposing a photo-sensitive silver emulsion, or pattern-wise laser sintering a substrate 40 coated with conductive ink. In an embodiment, a flexographic printing plate is formed using photolithographic techniques known in the art. Conductive ink is applied to the printing plate and then pattern-wise transferred to substrate 40. After patterned deposition, the conductive ink is cured.

Commercially available conductive inks including metallic particles are known in the art. In useful embodiments, the conductive inks include nano-particles, for example silver, in a carrier fluid such as an aqueous solution. The carrier fluid can include surfactants that reduce flocculation of the metal particles. Once deposited, the conductive inks are cured, for example by heating. The curing process drives out the solution and sinters the metal particles to form a metallic electrical conductor. In other embodiments, the conductive inks are powders that are pattern-wise transferred to a substrate and cured or are powders coated on a substrate and pattern-wise cured.

In any of these cases, conductive inks or other conducting materials are conductive after they are cured and any needed processing completed. Deposited materials are not necessarily electrically conductive before patterning or before curing. As used herein, a conductive ink is a material that is electrically conductive after any final processing is completed and the conductive ink is not necessarily conductive at any other point in micro-wire 50 formation process.

As described above with respect to FIGS. 1 and 3, in emboss- and fill methods of the present invention a pattern of micro-channels 60 is created on a substrate 40 with each micro-channel 60. A conductive ink is then coated over substrate 40 and into micro-channels 60. The excess conductive ink between micro-channels 60 is removed, for example by using a squeegee. The conductive inks include nano-particles, for example silver, in a carrier fluid such as an aqueous solution. Typical weight concentrations of the silver nano-particles range from 30% to 90%. Because of its high density, the volume concentration of silver in the solution is much lower, typically 4-50%. After filling micro-channels 60 with this conductive ink solution, the carrier fluid evaporates, resulting in a silver micro-wire 50 in micro-channel 60. The actual final silver thickness of silver micro-wire 50 depends on the filling method and silver concentration in the conductive ink solution.

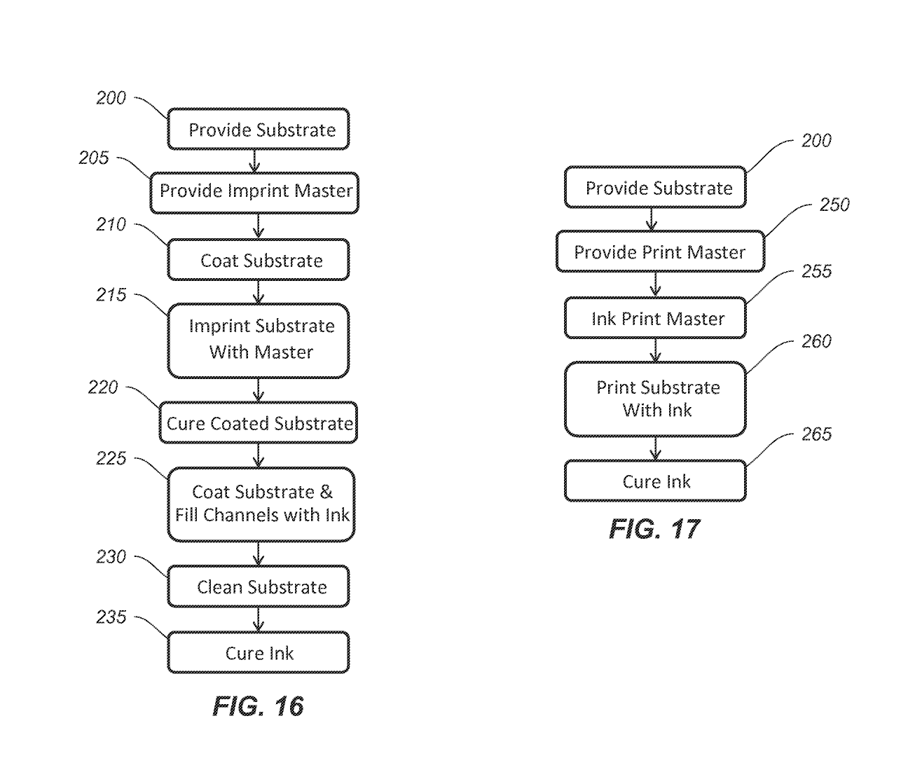

Referring to FIG. 16, in a method useful for making electrically conductive micro-wire structures 5 of the present invention, a substrate 40 is provided 200 and an imprint master is provided 205. Substrate 40 is coated 210, for example with a polymer and partially cured. The partially cured polymer coating is imprinted 215 with the print master and cured 220. Substrate 40 is coated 225 with a conductive ink, cleaned in step 230, and the remaining ink is cured 235.

Referring to an alternative method illustrated in FIG. 17, a substrate 40 is provided 200 and a print master (e.g. a flexographic printing plate) is provided 250. The print master is inked 255 with conductive ink and the ink is pattern-wise printed 260 on substrate 40. The conductive ink is cured 265.

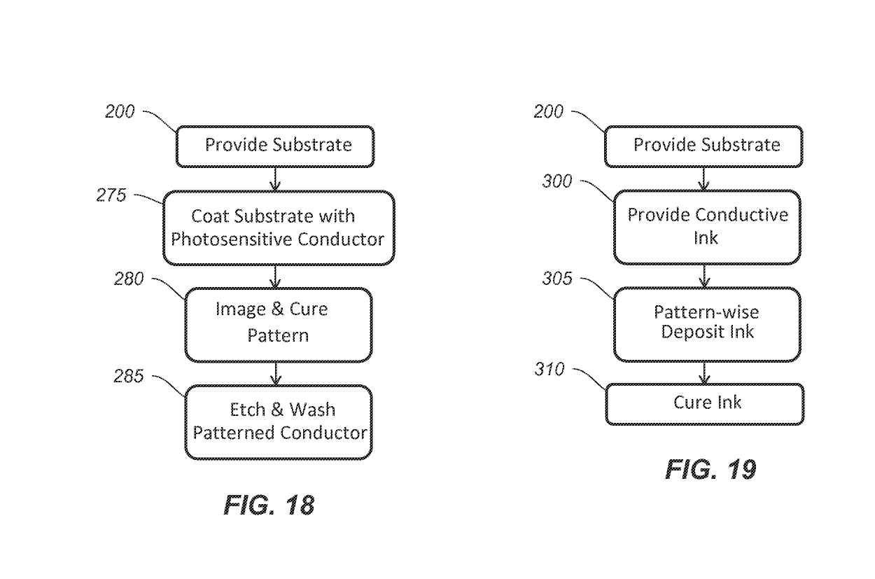

Referring to another alternative method illustrated in FIG. 18, a substrate 40 is provided 200 and coated 275 with a photosensitive conductor, for example a silver halide emulsion or a metal layer covered with a photo resist. The substrate 40 is exposed 280 to patterned radiation, for example with a laser or with electromagnetic radiation through a mask. The patterned photosensitive conductor is then cured if necessary, e.g. by fixing, and unwanted photosensitive conductor material removed 285 by etching or washing.

In yet another alternative method illustrated in FIG. 19, a substrate 40 is provided 200 and a conductive ink provided 300. The conductive ink is pattern-wise deposited 305 on substrate 40, for example using an inkjet apparatus, and the conductive ink is cured 310.

Electrically conductive micro-wire structure 5 of the present invention can be employed in electronic devices to conduct electricity across a substrate 40. Electrically conductive micro-wire structure 5 can be electrically connected to a transparent micro-wire electrode 46 having micro-wires 50 formed on substrate 40 through wires 134 to electronic controller 140 in a touch-screen device. Signals from electronic controller 140 pass through conventional wires 134 in electrical contact with micro-wires 50 to electrically conductive micro-wire structure 5. Electrically conductive micro-wire structure 5 conducts electrical signals to and from transparent micro-wire electrodes 46 to operate the touch-screen device.

Micro-wires 50 can be metal, for example silver, gold, aluminum, nickel, tungsten, titanium, tin, or copper or various metal alloys including, for example silver, gold, aluminum, nickel, tungsten, titanium, tin, or copper. Micro-wires 50 can be a thin metal layer composed of highly conductive metals such as gold, silver, copper, or aluminum. Other conductive metals or materials can be used. Alternatively, micro-wires 50 can include cured or sintered metal particles such as nickel, tungsten, silver, gold, titanium, or tin or alloys such as nickel, tungsten, silver, gold, titanium, or tin. Conductive inks can be used to form micro-wires 50 with pattern-wise deposition or pattern-wise formation followed by curing steps. Other materials or methods for forming micro-wires 50 can be employed and are included in the present invention.

Micro-wires 50 can be, but need not be, opaque. Micro-wires 50 can be formed by patterned deposition of conductive materials or of patterned precursor materials that are subsequently processed, if necessary, to form a conductive material. Suitable methods and materials are known in the art, for example inkjet deposition or screen printing with conductive inks. Alternatively, micro-wires 50 can be formed by providing a blanket deposition of a conductive or precursor material and patterning and curing, if necessary, the deposited material to form a micro-wire pattern 55 of micro-wires 50. Photo-lithographic and photographic methods are known to perform such processing. The present invention is not limited by the micro-wire materials or by methods of forming a micro-wire pattern 55 of micro-wires 50 on a supporting substrate surface.

In various embodiments, micro-wires 50 in electrically conductive micro-wire structure 5 are formed in a micro-wire layer that forms a conductive mesh of electrically connected micro-wires 50. If substrate 40 on or in which micro-wires 50 are formed is planar, for example, a rigid planar substrate such as a glass substrate, micro-wires 50 in a micro-wire layer are formed in, or on, a common plane as a conductive, electrically connected mesh forming electrically conductive micro-wire structure 5. If substrate 40 is flexible and curved, for example a plastic substrate, micro-wires 50 in a micro-wire layer are a conductive, electrically connected mesh that is a common distance from a surface 41 of flexible substrate 40.

Micro-wires 50 can be formed directly on substrate 40 or over substrate 40 on layers formed on substrate 40. The words “on”, “over’, or the phrase “on or over” indicate that micro-wires 50 of the electrically conductive micro-wire structure 5 of the present invention can be formed directly on a surface of substrate 40, on layers formed on substrate 40, or on either or both of opposing sides of substrate 40. Thus, micro-wires 50 of the electrically conductive micro-wire structure 5 of the present invention can be formed under or beneath substrate 40. “Over” or “under”, as used in the present disclosure, are simply relative terms for layers located on or adjacent to opposing surfaces of a substrate 40. By flipping substrate 40 and related structures over, layers that are over substrate 40 become under substrate 40 and layers that are under substrate 40 become over substrate 40.

In an example and non-limiting embodiment of the present invention, each micro-wire 50 is from 5 microns wide to one micron wide and is separated from neighboring micro-wires 50 by a distance of 20 microns or less, for example 10 microns, 5 microns, 2 microns, or one micron.

Methods and device for forming and providing substrates, coating substrates, patterning coated substrates, or pattern-wise depositing materials on a substrate are known in the photo-lithographic arts. Likewise, tools for laying out electrodes, conductive traces, and connectors are known in the electronics industry as are methods for manufacturing such electronic system elements. Hardware controllers for controlling touch screens and displays and software for managing display and touch screen systems are all well known. All of these tools and methods can be usefully employed to design, implement, construct, and operate the present invention. Methods, tools, and devices for operating capacitive touch screens can be used with the present invention.

The present invention is useful in a wide variety of electronic devices. Such devices can include, for example, photovoltaic devices, OLED displays and lighting, LCD displays, plasma displays, inorganic LED displays and lighting, electrophoretic displays, electrowetting displays, dimming mirrors, smart windows, transparent radio antennae, transparent heaters and other touch screen devices such as resistive touch screen devices.

The invention has been described in detail with particular reference to certain embodiments thereof, but it will be understood that variations and modifications can be effected within the spirit and scope of the invention.

### PARTS LIST

D depth
W width
W1 width
W2 width
W3 width
L length
C circle
5 electrically conductive micro-wire structure
10 first micro-wire
15 coincident portion
18 intersection corner
19 extension lines
20 second micro-wire
40 substrate
46 transparent micro-wire electrode
50 micro-wire
55 intersecting pattern
60 micro-channel
100 touch screen and display system
110 display
111 display area
120 touch screen
122 first transparent substrate
124 transparent dielectric layer
126 second transparent substrate
128 first pad area
129 second pad area
130 first transparent electrode
132 second transparent electrode
134 wires
136 buss connections
140 touch-screen controller
142 display controller
150 micro-wire
156 micro-pattern
200 provide substrate step
205 provide imprint master step
210 coat substrate step
215 imprint substrate with master step
220 cure coated substrate step
225 coat substrate and fill channels with ink step
230 clean substrate step
235 cure ink step
250 provide print master step
255 ink print master step
260 print substrate with ink step
265 cure ink step
275 coat substrate with photosensitive conductor step
280 image & cure pattern step
285 etch and wash patterned conductor step
300 provide conductive ink step
305 pattern-wise deposit ink step
310 cure ink step

1. A conductive micro-wire structure, comprising:
a substrate;
an array of first micro-wires arranged in a regular repeating pattern formed on or in the substrate, an array of second micro-wires arranged in a regular repeating pattern formed on or in the substrate, the array of first micro-wires intersecting with the array of second micro-wires at an angle forming intersection corners, wherein a portion of a first micro-wire is coincident with a portion of a second micro-wire to form a coincident portion such that the coincident portion has a length that is non-visually resolvable by the human visual system and the coincident portion has a length greater than the sum of the widths of the first and second micro-wires.

2. The conductive micro-wire structure of claim 1, wherein the substrate defines a plurality of micro-channels and wherein each of the plurality of micro-wires is located only in one micro-channel.

3. The conductive micro-wire structure of claim 2, wherein a cross section of at least one of the micro-channels is rectangular or trapezoidal.

4. The conductive micro-wire structure of claim 3 wherein the depth of the rectangular micro-channel is at least 2 microns and at most 10 microns.

5. The conductive micro-wire structure of claim 1, wherein the substrate defines a surface and wherein the plurality of micro-wires is located in or on the surface.

6. The conductive micro-wire structure of claim 1 wherein the micro-wires include metals or metal alloys.

7. The conductive micro-wire structure of claim 6 wherein the metals or metal alloys include gold, silver, aluminum, titanium, copper, or tin.

8. The conductive micro-wire structure of claim 1 wherein the micro-wires include sintered nano-particles.

9. The conductive micro-wire structure of claim 1 wherein the substrate is a cured polymer and wherein the substrate is substantially transparent.

10. The conductive micro-wire structure of claim 9 wherein the micro-wires are embossed in the cured polymer.

11. The conductive micro-wire structure of claim 1 wherein the conductive micro-wire structure forms a substantially transparent electrode.

12. The conductive micro-wire structure of claim 10 further including an electronic device having integrated circuits that control the substantially transparent electrode.

13. The conductive micro-wire structure of claim 1 wherein the coincident portion has a length less than a predetermined viewing distance multiplied by the tangent of a predetermined human resolution angle such that the intersections of the micro-wires are not visually resolvable.

14. A conductive micro-wire structure, comprising:
a substrate;
an array of first micro-wires arranged in a regular repeating pattern formed on or in the substrate; and
an array of second micro-wires arranged in a regular repeating pattern formed on or in the substrate intersecting with the first micro-wires and forming intersection corners; and
wherein at least one intersection corner joining one of the first micro-wires with one of the second micro-wires is rounded and has a radius of curvature greater than one quarter of the width of the first or second micro-wires.

15. The conductive micro-wire structure of claim 14 wherein the micro-wires are embossed in the substrate.

16. The micro-wire structure of claim 14, wherein the radius of curvature of the one or more intersection corners has a radius of curvature greater than or equal to one third of the first or second micro-wire width.

17. The micro-wire structure of claim 14, wherein the radius of curvature of the one or more intersection corners has a radius of curvature greater than or equal to one half of the first or second micro-wire width.

18. The micro-wire structure of claim 14, wherein the width of the first micro-wire is equal to the width of the second micro-wire.

19. The conductive micro-wire structure of claim 14 wherein the substrate is an embossed polymer.

20. The conductive micro-wire structure of claim 1 wherein the coincident portion has one or more rounded intersection corners.
